(19) United States
(12) Patent Application Publication
(10) Pub. No.: US 2006/0021578 A1
(43) Pub. Date: Feb. 2, 2006

(54) Chemical vapor deposition apparatus

(76) Inventors: Jung-Hun Seo, Gyeonggi-do (KR); Young-Wook Park, Gyeonggi-do (KR); Jin-Gi Hong, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/155,206

(22) Filed: Jun. 16, 2005

(30) Foreign Application Priority Data
Jul. 28, 2004 (KR) 2004-58969

(51) Int. Cl. C23C 16/00

(52) U.S. Cl. 118/719

(57) ABSTRACT

A chemical vapor deposition apparatus and method are provided. The apparatus includes a heater disposed on a bottom of a process chamber for heating a wafer laid on the heater. A shower head is disposed above the heater for injecting a reaction gas. The apparatus comprises a shutter chamber provided at an outer side of the process chamber. A transfer robot is installed in the shutter chamber having a blade at a front end thereof. The transfer robot is reciprocated within the process chamber by driving device. A shutter disk is laid on the blade of the transfer robot. The shutter disk is located on the heater of the process chamber by the transfer robot to prevent radiant heat generated from the heater from being transferred to the shower head.

### CROSS-REFERENCE TO RELATED APPLICATION

This application claims the benefit of Korean Patent Application No. 2004-58969, filed Jul. 28, 2004, the disclosure of which is hereby incorporated herein by reference in its entirety.

### BACKGROUND OF THE INVENTION

1. Technical Field

The present invention relates to a chemical vapor deposition apparatus, and more particularly, to a chemical vapor deposition apparatus capable of loading/unloading a shutter disk into/from a shutter chamber provided to one side of a process chamber to prevent heat from being transferred to a shower head from a heater, while maintaining a running atmosphere intact, during an idle period of a process, thereby reducing particles at performing the process and improving throughput.

2. Discussion of Related Art

In general, in process of manufacturing of certain semiconductor devices, a Ti/TiN film can be deposited by sputtering or chemical vapor deposition, which is generally used as a barrier metal in a process of forming a metal wiring.

The Ti/TiN film can be formed by reaction of TiCl₄ and NH₃. Temperature control can be a very important parameter in view of reproducibility of deposition and particle control in the process. In particular, it can be very important to control the temperature at running or idle of process.

A conventional chemical vapor deposition apparatus includes, as shown in FIG. 1, a process chamber having a reaction chamber 11 therein, a heater 12 disposed on a bottom of the reaction chamber 11 for heating a wafer laid on the heater, and a shower head 13 disposed directly above the heater 12 for injecting a reaction gas of film substance to be deposited on the wafer laid on the heater.

For the shower head 13 or a chamber wall 10a for injecting the reaction gas in the process chamber 10, it can be very stable to keep the shower head or chamber wall at a temperature of about 150 to 250° C. during processing. If the temperature is below 150° C., NH₄Cl can be generated. If the temperature is below 50° C., TiCl₄ can be coagulated. In addition, if the temperature is above 250° C., by-products of TiₓNCl_{y} can be generated. Therefore, it is very important to keep the shower head or chamber wall at a controlled temperature, and preferably at a constant temperature.

In particular, since a thin film can be plasma-deposited with Ti formed by reactions of TiCl₄ and H₂, the shower head has to be maintained at a temperature of about 150 to 250° C. To this end, the internal temperature of the process chamber has to be maintained at a temperature of above 450° C. to prevent deposition of TiClₓ or production of particles.

Accordingly, since the temperature control of the shower head 13 plays an important part in maintenance and operation of the equipment, the temperature of the shower head should be independently controlled in an operational state and in an idle state.

The wafer is laid on the heater at the running of the process, while the wafer is removed from the heater in the idle state. In the idle state, since the heater 12 directly faces the shower head 13, the temperature of the shower head 13 is raised by radiant heat generated from the heater 12. Therefore, it causes deposition characteristics to be changed according to the number of wafers in progress of the process.

When the process is running in the state where the temperature of the shower head 13 is raised by the radiant heat, the reaction gas is injected from the shower head 13, thereby producing a lot of particles.

In order to solve the above drawback, the heater is maintained at a low temperature of about 300° C. during idle, while the temperature of the heater is raised to about 600 to 700° C. during operation. Since the temperature of the heater is raised at the rate of 5° C. a minute, it causes an uneconomical delay in the process for at least an hour until the operational temperature can be re-established.

### SUMMARY OF THE INVENTION

Therefore, the present invention is directed to provide a chemical vapor deposition apparatus capable of solving the above problems.

An object of the present invention is to provide a chemical vapor deposition apparatus capable of preventing production of particles during performing a process by maintaining a shower head at a same temperature during idle and operation.

Another object of the present invention is to provide a chemical vapor deposition apparatus capable of preventing an unnecessary process delay by maintaining a shower head at substantially the same temperature during idle and operation, thereby remarkably improving throughput.

A chemical vapor deposition apparatus is provided including a heater disposed on a bottom of the process chamber for heating a wafer laid on the heater. A shower head is disposed above the heater for injecting a reaction gas. The apparatus further comprises a shutter chamber provided at an outer side of the process chamber. A transfer robot is installed in the shutter chamber. The transfer robot has a blade at a front end thereof which is reciprocated, preferably in a substantially straight path, within the process chamber by driving device. A shutter disk is laid on the blade of the transfer robot. The shutter disk is located on the heater of the process chamber by the transfer robot to prevent radiant heat generated from the heater from being transferred to the shower head.

The shutter chamber is preferably in communication with the process chamber through a slit penetrating a chamber wall. Preferably, the slit is of a predetermined size. The slit of the shutter chamber is preferably closed by a door located in an outer side of the chamber wall. The door is preferably movable in an upward and a downward direction. The shutter chamber is preferably disposed in an outer wall of the process chamber opposite to a slit in the process chamber through which a wafer is loaded or unloaded. The driving device for the transfer robot preferably comprises a cylinder and/or a motor. In the case of a motor, the motor is preferably coupled to one end of a robot arm, and the other end of the robot arm is coupled to one end of the blade to move the blade.

The shutter disk preferably has an outer diameter larger than an outer diameter of the heater for the process chamber. Preferably, the shutter disk comprises AlN or Al₂O₃. Moreover, the shutter disk preferably has a mirror surface.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a vertically cross-sectional view illustrating a process chamber for a conventional chemical vapor deposition apparatus;

FIG. 2 is a plan view of a chemical vapor deposition apparatus according to an embodiment of the present invention;

FIG. 3 is a plan view illustrating a shutter disk moved by a driving device in a chemical vapor deposition apparatus according to an embodiment of the present invention; and

FIG. 4 is a vertically cross-sectional view illustrating an operating state of a chemical vapor deposition apparatus according to another embodiment of the present invention.

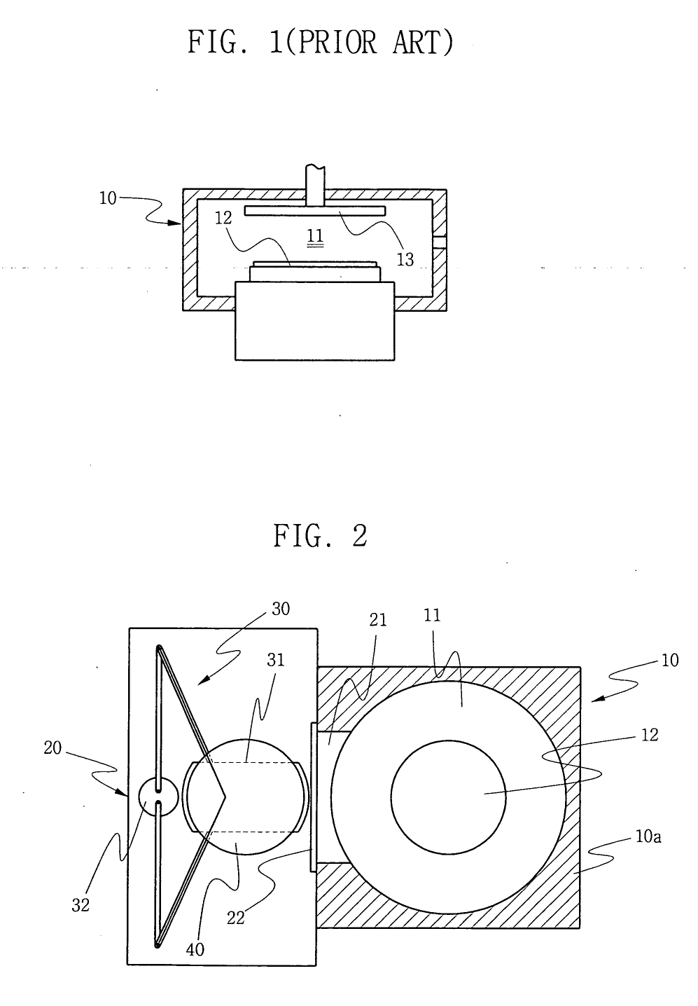

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided as teaching examples of the invention. Like numbers refer to like elements.

Referring to FIG. 2 illustrating a chemical vapor deposition apparatus according to the present invention, the apparatus includes a process chamber having a reaction chamber 11 therein, a heater 12 disposed on a bottom of the reaction chamber 11 for heating a wafer laid on the heater, and a shower head 13 disposed above the heater 12 for injecting a source gas of film substance, i.e., a reaction gas, to be deposited on the wafer laid on the heater, which is similar to that of a conventional chemical vapor deposition apparatus.

According to the present invention, the process chamber 10 is provided at an outer side thereof with a shutter chamber 20. The shutter chamber 20 includes a transfer robot 30 for locating a shutter disk 40 on the heater 12 of the process chamber 10.

Specifically, the shutter chamber 20 is disposed at one outer side of the process chamber 10, and has a sealed cavity communicating with the process chamber 10 through a slit 21 penetrating a chamber wall 10a at a predetermined size.

The slit 21 can isolate the process chamber 10 from the shutter chamber 20 using a door 22 which is movable up and down at an outer side of the chamber wall 10a of the shutter chamber 20.

Preferably, the shutter chamber 20 is disposed opposite to a slit (not shown) of the process chamber 10 through which the wafer is loaded/unloaded.

The transfer robot 30 is installed in the shutter chamber 20, and has a blade 31 at a front end of the process chamber 10. The blade 31 may be directly reciprocated into the reaction chamber 11 of the process chamber 10 by a driving device 32. At that time, the blade 31 is moved from the shutter chamber 20 to an upper portion of the heater 12 in the process chamber 10 by the driving device 32.

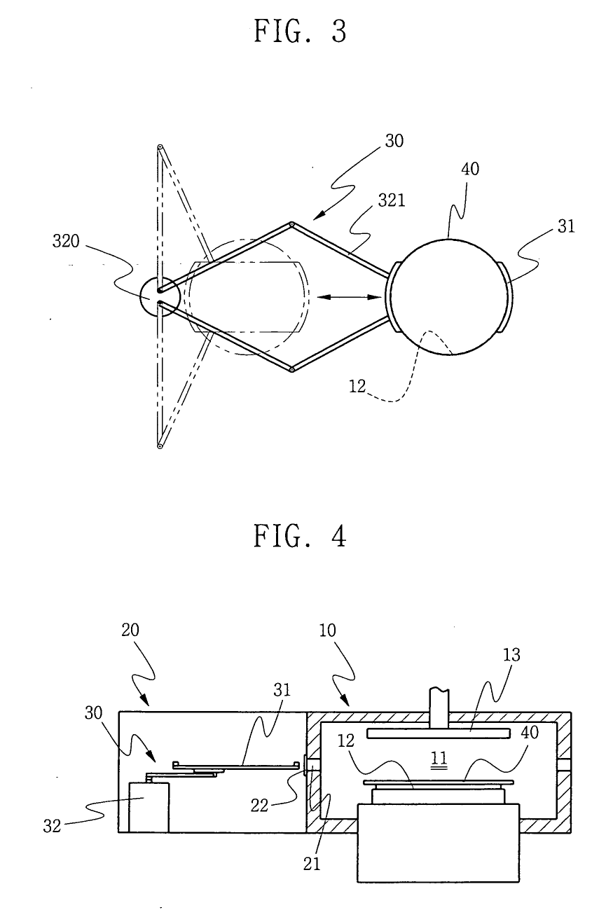

The driving device 32 of the transfer robot 30 employs a cylinder assembly, or a motor shown in FIG. 3. In particular, when a motor 320 is employed, the blade 31 is preferably coupled to the robot arm 321.

The shutter disk 40 is always laid on the blade 31 of the transfer robot 30 in the shutter chamber 20. The shutter disk 40 is put on the upper surface of the heater 12 in the process chamber 10 by the driving device 32 of the transfer robot 30.

The shutter disk 40 is disposed on the upper surface of the heater 12 to serve as heat block, i.e., to prevent radiant heat generated from the heater 12 from being transferred to the shower head 13 installed in the upper portion of the reaction chamber 11 of the process chamber 10.

Preferably, the shutter disk 40 has an outer diameter equal to or larger than the upper surface of the heater 12, but the outer diameter may be slightly smaller than the upper surface of the heater.

Since the shutter disk 40 is in closely contact with the heater 12, the shutter disk 40 is made of a material having a low heat transfer coefficient and lower modulus of heat strain. Preferably, the shutter disk is made of AlN or Al₂O₃.

In particular, the shutter disk 40 preferably has a relatively bright mirror surface.

In the process chamber 10, the chamber wall 11 is made of nickel or aluminum coated with nickel. The nickel may be utilized as the material of the shutter disk 40.

Operation of the present invention will now be described in detail.

The shutter chamber 20 is provided at one outer side of the process chamber 10 in communication with the process chamber 10. The shutter disk 40 is loaded into the process chamber 20 from the shutter chamber, preferably over a constant time period. In this way, the shutter disk 40 can be put on the upper surface of the heater 12 of the process chamber 20.

Specifically, when performing the process in the process chamber 10, the shutter chamber 20 can be accessed from the process chamber 10 via the door 22. At that time, the process chamber and the shutter chamber are in communication with each other.

Upon idling, i.e., when the process has been completed, or the process is temporarily interrupted to displace a cassette, the door 22 is opened, and simultaneously, the shutter disk 40 is loaded onto the upper portion of the heater 12 of the process chamber 10 from the shutter chamber 20 by the transfer robot 30. At that time, the lift pins (not shown) are lifted from the heater 12, and simultaneously, the blade 31 of the transfer robot 30 is returned to the shutter chamber 20 to put the shutter disk 40 on the upper surface of the heater 12.

Immediately after the blade 31 is returned to the shutter chamber 20, the process chamber 10 is again shielded from the shutter chamber 20 by the door 22, as shown in FIG. 4.

The shutter disk 40 put on the upper surface of the heater 12 is in contact with the heater 12 through the lift pins of the heater 12. However, since the shutter disk 40 is made of material having a low heat transfer coefficient, the radiant heat generated from the heater 12 is not transferred to the shower head 13 disposed above the heater.

If the shower head 13 is not heated during idle, the temperature of the heater 12 may be maintained at the same level as that during operation. When the idle condition is converted into the operational condition, the process may be performed in a stably intact manner by simply moving only the shutter disk 40 to the shutter chamber 20. Accordingly, the present invention can solve the problem of delaying the process time when it is required to raise the temperature of the heater 12.

That is, according to a conventional apparatus, the temperature of the heater 12 is typically lowered to about 300° C. under the idle condition. But the temperature of the heater is raised to about 600 to 700° C. to perform a deposition process. Therefore, the process has to be delayed for a period of time so as to raise the temperature of the heater. Therefore, the present invention overcomes the process delay.

More specifically, where the reaction chamber 11 is maintained under the same condition as the operational condition, the process chamber 10 may be maintained under the idle condition by putting the shutter disk 40 on the upper surface of the heater 12. After the shutter disk 40 is removed from the heater 12 and is then moved to the shutter chamber 20, the deposition process can be stably performed at conventional operating temperature conditions by putting the wafer on the heater 12.

Meanwhile, if the shutter chamber 20 is provided to one side of the process chamber 10 in a direction opposite to the loading direction of the wafer. The present invention may also be applied to a multi chamber type of apparatus.

The present invention may maintain the process atmosphere under operating conditions by putting the shutter disk 40 on the heater 12 of the process chamber 10 from the shutter chamber 20 when the operational state is converted into the idle state. When the wafer and wafer cassette are disposed at a load lock position, the shutter disk 40 is accommodated in an interior of the shutter chamber 20. Thus, the reaction chamber 11 of the process chamber 10 can be maintained under the same condition as the operating conditions, which in turn maintains the continuation of the process. In addition, it can prevent production of unwanted particles when the reaction gas is introduced from an overheated showerhead 13 into the reaction chamber.

Accordingly, the time required to convert the idle atmosphere into the operational atmosphere is maximally shortened, thereby more effectively and efficiently performing the process and thus improving throughput.

With the above description, according to an aspect of the present invention, the shutter chamber 20 is connected to one side of the process chamber 10, so that the shutter disk 40 can be directly reciprocated from the shutter chamber 20 to the upper portion of the heater 12 in the process chamber 10. The reaction chamber may always be maintained in an operational mode by loading and unloading the shutter disk 40 onto the upper surface of the heater 12 when converting from the operational state into the idle state and vice versa. As a result, the operational time is significantly reduced so as to improve the throughput, and the production of unwanted particles is substantially prevented.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. For example, it is apparent that the value of reference temperature of the hot plate may be automatically set or changed according to an environmental temperature or sensing or controlling method. The scope of the claims, therefore, should be accorded the broadest interpretation so as to encompass all such modifications and similar arrangements.

What is claimed is:

1. A chemical vapor deposition apparatus including a heater disposed on a bottom of the process chamber for heating a wafer laid on the heater, and a shower head disposed above the heater for injecting a reaction gas, comprising:
a shutter chamber provided at an outer side of the process chamber;
a transfer robot installed in the shutter chamber and having a blade at a front end thereof which is reciprocated within the process chamber by a driving device; and
a shutter disk laid on the blade of the transfer robot, the shutter disk being located on the heater of the process chamber by the transfer robot to prevent radiant heat generated from the heater from being transferred to the shower head.

2. The chemical vapor deposition apparatus according to claim 1, wherein the shutter chamber is in communication with the process chamber through a slit penetrating a chamber wall.

3. The chemical vapor deposition apparatus according to claim 2, wherein the slit of the shutter chamber is closed by a door located in an outer side of the chamber wall.

4. The chemical vapor deposition apparatus according to claim 1, wherein the shutter chamber is disposed in an outer wall of the process chamber opposite to a slit in the process chamber through which a wafer is loaded or unloaded.

5. The chemical vapor deposition apparatus according to claim 1, wherein the driving device for the transfer robot comprises a cylinder.

6. The chemical vapor deposition apparatus according to claim 1, wherein the driving device for the transfer robot comprises a motor.

7. The chemical vapor deposition apparatus according to claim 6, wherein the motor is coupled to one end of a robot arm, and wherein the other end of the robot arm is coupled to one end of the blade to move the blade.

8. The chemical vapor deposition apparatus according to claim 1, wherein the shutter disk has an outer diameter larger than an outer diameter of the heater for the process chamber.

9. The chemical vapor deposition apparatus according to claim 1, wherein the shutter disk is comprises AlN or Al₂O₃.

10. The chemical vapor deposition apparatus according to claim 1, wherein the shutter disk has a mirror surface.

11. A method for chemical vapor deposition, comprising:
providing an apparatus including a heater disposed on a bottom of a process chamber for heating a wafer laid on the heater, and a shower head disposed above the heater for injecting a reaction gas;
providing a shutter chamber at an outer side of the process chamber;
providing a transfer robot installed in the shutter chamber, said transfer robot having a blade which is reciprocated within the process chamber;
providing a shutter disk;
laying said shutter disk on a blade of the transfer robot; and
locating the shutter disk on the heater of the process chamber using the blade of the transfer robot for preventing radiant heat generated from the heater from being transferred to the shower head.

12. The method according to claim 11, wherein the shutter chamber is in communication with the process chamber through a slit penetrating a chamber wall.

13. The method according to claim 12, wherein the slit of the shutter chamber is closed by a door located in an outer side of the chamber wall.

14. The method according to claim 11, wherein the shutter chamber is disposed in an outer wall of the process chamber opposite to a slit in the process chamber through which a wafer is loaded or unloaded.

15. The method according to claim 11, wherein the driving device for the transfer robot comprises a cylinder.

16. The method according to claim 11, wherein the driving device for the transfer robot comprises a motor.

17. The method according to claim 16, wherein the motor is coupled to one end of a robot arm, and the other end of the robot arm is coupled to one end of the blade to move the blade.

18. The method according to claim 11, wherein the shutter disk has an outer diameter larger than an outer diameter of the heater for the process chamber.

19. The method according to claim 11, wherein the shutter disk is comprises AlN or Al₂O₃.

20. The method according to claim 11, wherein the shutter disk has a mirror surface.
